(19) United States
(12) Patent Application Publication
(10) Pub. No.: US 2026/0319373 A1
(43) Pub. Date: Oct. 15, 2026

(54) Systems, Methods, And Devices For Spectrometers Associated With Microscopes

(71) Applicant: EUV Tech, Inc., Martinez, CA (US)

(72) Inventor: Patrick Naulleau, Pleasant Hill, CA (US)

(21) Appl. No.: 19/174,578

(22) Filed: Apr. 9, 2025

(51) Int. Cl. G03F 7/00; G02B 27/42

(52) U.S. Cl. CPC G03F 7/70158; G02B 27/4222; G03F 7/70141; G03F 7/705; G03F 7/70575

(57) ABSTRACT

Systems, methods, and devices disclosed herein implement spectrometers associated with lithography operations. Systems include a light source configured to generate a first optical output, a diffractive optic configured to receive at least a portion of the first optical output from the light source, the diffractive optic being configured to generate a first image when in a first position, and further configured to generate a second image when in a second position, the second image having a designated amount of linear dispersion, an imaging device configured to receive at least the second image, a computing device comprising one or more processors configured to generate one or more performance metrics for the light source based, at least in part, on the second image.

### FIELD OF TECHNOLOGY

This patent application relates generally to lithography optics, and more specifically to spectrometers used with such lithography optics.

### BACKGROUND

Lithography techniques may use one or more patterning techniques to apply a pattern to a lithography target. For example, photolithography may use light to induce changes in the lithography target that may subsequently be used to etch a pattern in the lithography target. The pattern itself may be represented in a photomask which may be used in combination with a resist that coats the lithography target itself. Imaging optics may be used to obtain images of the mask and evaluate properties of the mask layer. Conventional techniques for such mask imaging remain limited because they can experience loss in imaging resolution due to decreased performance in one or more imaging components, such as a monochromator.

### SUMMARY

In some embodiments, techniques described herein relate to a system for implementation of a spectrometer. In some embodiments, the techniques described herein relate to a system including: a light source configured to generate a first optical output; a diffractive optic configured to receive at least a portion of the first optical output from the light source, the diffractive optic being configured to generate a first image when in a first position, and further configured to generate a second image when in a second position, the second image having a designated amount of linear dispersion; an imaging device configured to receive at least the second image; and a computing device including one or more processors configured to generate one or more performance metrics for the light source based, at least in part, on the second image.

In some embodiments, the techniques described herein relate to a system, wherein the light source includes a monochromator, and wherein the first optical output is used to illuminate a target mask associated with lithography operations. In some embodiments, the techniques described herein relate to a system, wherein the diffractive optic includes: a first zone plate configured to generate the first image; and a second zone plate configured to generate the second image. In some embodiments, the techniques described herein relate to a system, wherein the diffractive optic is configured to toggle between a first position and a second position, the first position exposing the first zone plate to the at least a portion of the first optical output, and the second position exposing the second zone plate to the at least a portion of the first optical output.

In some embodiments, the techniques described herein relate to a system, wherein the first zone plate and the second zone plate are implemented on a same optical membrane. In some embodiments, the techniques described herein relate to a system, wherein the linear dispersion is generated based, at least in part, on diffractive features of the second zone plate. In some embodiments, the techniques described herein relate to a system, wherein the one or more performance metrics are generated based, at least in part, on a magnitude of the linear dispersion included in the second image.

In some embodiments, the techniques described herein relate to a system, wherein the computing device is further configured to adjust one or more operational parameters of the light source based on the one or more performance metrics. In some embodiments, the techniques described herein relate to a system, wherein the adjusting includes: adjusting a setting of the light source.

In some embodiments, the techniques described herein relate to a device including: a diffractive optic configured to receive at least a portion of a first optical output from a light source, the diffractive optic being configured to generate a first image when in a first position, and further configured to generate a second image when in a second position, the second image having a designated amount of linear dispersion; one or more imaging sensors configured to receive at least the second image; and one or more processors configured to generate one or more performance metrics for the light source based, at least in part, on the second image.

In some embodiments, the techniques described herein relate to a device, wherein the light source includes a monochromator, and wherein the first optical output is used to illuminate a target mask associated with lithography operations. In some embodiments, the techniques described herein relate to a device, wherein the diffractive optic includes: a first zone plate configured to generate the first image; and a second zone plate configured to generate the second image. In some embodiments, the techniques described herein relate to a device, wherein the diffractive optic is configured to toggle between a first position and a second position, the first position exposing the first zone plate to the at least a portion of the first optical output, and the second position exposing the second zone plate to the at least a portion of the first optical output.

In some embodiments, the techniques described herein relate to a device, wherein the first zone plate and the second zone plate are implemented on a same optical membrane, and wherein the linear dispersion is generated based, at least in part, on diffractive features of the second zone plate. In some embodiments, the techniques described herein relate to a device, wherein the one or more performance metrics are generated based, at least in part, on a magnitude of the linear dispersion included in the second image, and wherein the one or more processors are further configured to adjust one or more operational parameters of the light source based on the one or more performance metrics.

In some embodiments, the techniques described herein relate to a method including: receiving at least a portion of a first optical output from a light source; selecting a position of a diffractive optic, the diffractive optic being toggleable between a first position used to generate a first image and a second position used to generate a second image; generating, using the diffractive optic, a second image when in a second position, the second image having a designated amount of linear dispersion determined based, at least in part, on diffractive features of the diffractive optic; receiving the second image at an imaging device; and generating, using one or more processors, one or more performance metrics for the light source based, at least in part, on the second image.

In some embodiments, the techniques described herein relate to a method, wherein the light source includes a monochromator, and wherein the first optical output is used to illuminate a target mask associated with lithography operations. In some embodiments, the techniques described herein relate to a method, wherein the diffractive optic includes a first zone plate and a second zone platen, and wherein the method further includes: generating, using the second zone plate, the second image. In some embodiments, the techniques described herein relate to a method, wherein the first zone plate and the second zone plate are implemented on a same optical membrane, and wherein the linear dispersion is generated based, at least in part, on diffractive features of the second zone plate.

In some embodiments, the techniques described herein relate to a method, wherein the one or more performance metrics are generated based, at least in part, on a magnitude of the linear dispersion included in the second image, and wherein the method further includes: adjusting one or more operational parameters of the light source based on the one or more performance metrics. These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, methods, and devices for implementation of spectrometers. These drawings in no way limit any changes in form and detail that may be made by one skilled in the art without departing from the spirit and scope of the disclosed implementations.

FIG. 1 illustrates an example of a system for a spectrometer, configured in accordance with some embodiments.

FIG. 2 illustrates an example of a device for a spectrometer, configured in accordance with some embodiments.

FIG. 3 illustrates an example of a mask pattern, configured in accordance with some embodiments.

FIG. 4 illustrates an example of a diffractive optic image, configured in accordance with some embodiments.

FIG. 5 illustrates another example of a diffractive optic image, configured in accordance with some embodiments.

FIG. 6 illustrates an example of a method for spectrometry, performed in accordance with some embodiments.

FIG. 7 illustrates another example of a method for spectrometry, performed in accordance with some embodiments.

### DETAILED DESCRIPTION

Lithographic masks may be used to support various lithography operations used to etch patterns in lithography targets. Moreover, imaging devices may be used to obtain images of such masks to ensure that the masks are sufficiently uniform to be used in such lithography operations. In various embodiments, such imaging devices may utilize monochromators as a light source for such lithography mask microscopy. During such microscopy operations, poor monochromator performance may reduce overall performance of an imaging device as chromatic artefacts introduced by such poor performance may reduce an overall resolution of the imaging device. Conventional techniques remain limited in their ability to maintain improved performance of such monochromators.

Embodiments disclosed herein provide in-situ assessments of monochromator performance to ensure that monochromator performance is maintained within a designated range of operation and does not fall below a designated performance threshold during imaging operations. As will be discussed in greater detail below, imaging devices may be configured to have a second imaging pathway that is configured to use dispersion features of the optical output of the monochromator to generate an assessment of such monochromator performance. For example, a linear dispersion represented in the second imaging pathway may allow direct measurement of monochromator performance based on spectral resolution. Such a measurement may be provided as in-situ feedback for monochromator tuning that may occur dynamically and in real-time thus allowing for use of such feedback to implement dynamic monochromator tuning in the field.

Moreover, as will be discussed in greater detail below, embodiments disclosed herein may be integrated with zone plate systems that utilize diffractive optics, such as zone plates, which may be more compact and more efficiently implemented than mirror-based systems. Accordingly, as will be discussed in greater detail below, zone plate-based imaging devices may be configured to implement such in-situ monochromator performance evaluation and feedback, and dynamic tuning of such imaging devices that may be implemented in extreme ultraviolet (EUV) contexts.

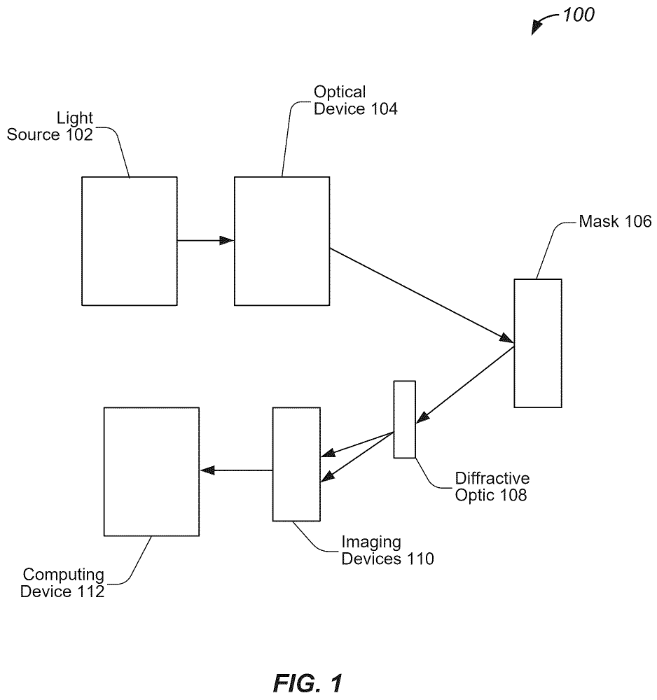

FIG. 1 illustrates an example of a system for a spectrometer, configured in accordance with some embodiments. As similarly discussed above, embodiments disclosed herein generate in-situ assessments of monochromator performance to enable improved performance of monochromators that may be implemented in imaging systems, that may include microscopes, used to perform imaging operations associated with lithography operations, as may be implemented during EUV lithography. As will be discussed in greater detail below, imaging systems, such as system 100, may be configured to have a second imaging pathway that is configured to use dispersion features of the optical output of the monochromator to generate an assessment of such monochromator performance.

In various embodiments, system 100 includes light source 102 which is configured to generate light used for imaging and microscopy operations described herein. In various embodiments, light source 102 is configured to generate a narrow band of wavelengths for such imaging operations. In one example, light source 102 may include a monochromator that is configured to transmit a selectable band of wavelengths of light from a wider available range of wavelengths. In various embodiments, performance parameters of light source 102 may be sensitive to various operational parameters and conditions, such as alignment variances and thermal effects during different operations, such as tool operations and/or vent/pump operations. As will be discussed in greater detail below, embodiments disclosed herein provide the ability to dynamically observe and tune such performance parameters to ensure improved operation of light source 102. It will be appreciated that any suitable technique for implementing a monochromator is contemplated and disclosed herein. Moreover, in some embodiments, one or more optical elements, such as optical device 104, may be included for focusing or other optical transformation of an output generated by light source 102.

In various embodiments, system 100 additionally includes a lithography target, such as mask 106. As similarly discussed above, mask 106 may be disposed on a substrate, such as a quartz plate, that will undergo lithography operations. As shown in FIG. 1, the optical output of optical device 104 may be provided to mask 106 and the optical output may reflect off of mask 106, and may be received at a diffractive optic, such as diffractive optic 108. It will be appreciated that optical device 104 may be optionally included. Accordingly, in some embodiments, system 100 does not include optical device 104, and an output of light source 102 is provided directly to mask 106.

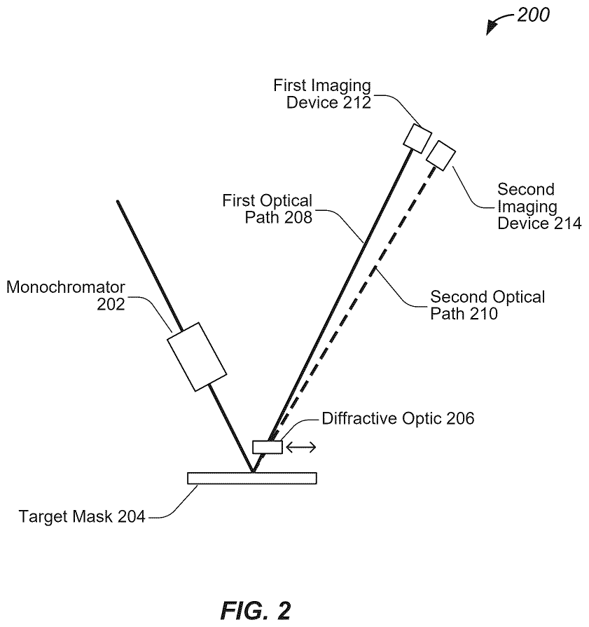

In various embodiments, diffractive optic 108 may receive light reflected off of mask 106 and may generate an optical output based on such received light. As will be discussed in greater detail below with reference to FIG. 2, a position of diffractive optic 108 may be configurable such that at a first position, diffractive optic 108 is configured to generate a first image along a first optical path. Moreover, diffractive optic 108 is further configured to move to a second position to generate a second image along a second optical path. In some embodiments, the first image of the first optical path may be used in a first operational mode used during microscopy operations that may be associated with lithography operations. More specifically, during the first operational mode, microscopy operations may be performed where an image of mask 106 is projected onto an imaging device, as will be discussed in greater detail below. Moreover, the second image of the second optical path may be used in a second operational mode used for spectroscopy operations used to assess performance of light source 102.

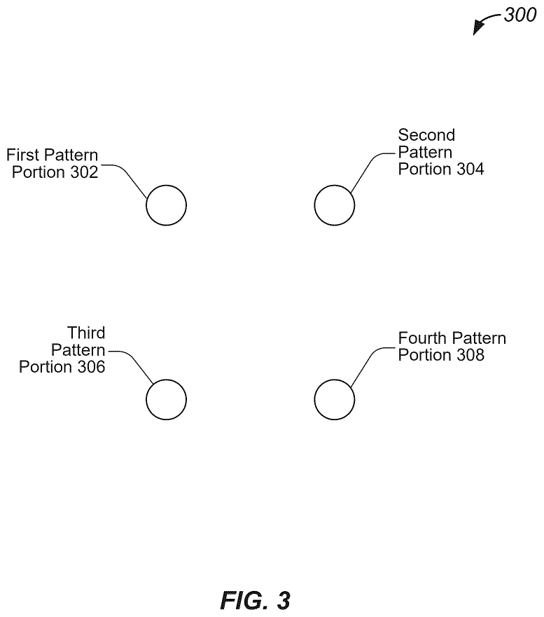

In various embodiments, diffractive optic 108 includes one or more zone plates that are configured to include optical gratings. More specifically, diffractive optic 108 may include a first zone plate that is configured to be used for EUV imaging and lithography operations. Diffractive optic 108 may further include a second zone plate that is configured to be used for spectroscopy operations that assess the performance of the monochromator. As will be discussed in greater detail below, the second zone plate may be integrated onto a spatial frequency carrier, and may apply an additional linear dispersion term that can be used to measure the spectral resolution of the monochromator. As will be discussed in greater detail below with reference to FIGS. 3-5, such an additional linear dispersion term may be implemented using a sparse array of contacts. The linear dispersion added to the zone plate will cause the projected image of the patterns mask 106 to be elongated in one direction with the elongation being directly proportional to the monochromator resolution.

As will be discussed in greater detail below with reference to FIGS. 3-5, the patterns on mask 106 may be configured to be a sparse array of contacts making the effect of the dispersion more predictable. Accordingly, a pattern on mask 106 itself may be configured to facilitate spectroscopy operations and spectral resolution measurements disclosed herein. Moreover, as will discussed in greater detail below, while various embodiments disclosed herein describe a sparse array, any suitable imaging pattern may be used. In some embodiments, both the first zone plate and the second zone plate may be patterned on a single membrane. In this way, two diffractive patterns may be patterned on a single diffractive optic, and a position of the diffractive optic may be changed to determine which diffractive pattern is being used.

In various embodiments, diffractive optic 108 may be included in a housing and coupled to one or more mechanical components configured to change a physical location of diffractive optic 108 along an axis of motion, thus enabling toggling of diffractive optic 108 between the first position and the second position. Such mechanical components may be positioning rails or any other suitable positioning mechanism. In various embodiments, a position of diffractive optic 108 may be controlled via manual actuation of such positioning mechanisms, and/or may be controlled via electromechanical motors controlled via a control signal received from a computing device, such as computing device 112 discussed in greater detail below. Accordingly, an entity, such as a user, may provide an input to computing device 112 via a user interface to change the position of diffractive optic 108. In another example, computing device 112 may change such position automatically based on one or more operational parameters. For example, such a change in position may be performed based on a passage of an amount of time for a periodic implementation of spectroscopy operations. In another example, such a change in position may be performed based on one or more operational conditions, such as a termination of a lithography operation, for a dynamic implementation of spectroscopy operations.

Optical outputs of diffractive optic 108 may be provided to imaging devices 110. As will be discussed in greater detail below, imaging devices 110 may include multiple imaging devices such as a first imaging sensor and a second imaging sensor. Such sensors may be implemented in different cameras. In another example, multiple sensors may be implemented in a single camera. In an additional example, a single camera includes a single imaging sensor, but is configured to move locations defined by a physical position for different image capture operations of a first and second optical path, as will be discussed in greater detail below with reference to FIG. 2. In various embodiments, the imaging sensors may be any suitable imaging sensor capable of capturing images of mask 106. For example, imaging sensor may include a charge-coupled device (CCD) sensor or a complementary metal-oxide-semiconductor (CMOS) sensor configured to capture a digital image of mask 106, and provide such imaging data to a computing device, such as computing device 112.

In various embodiments, computing device 112 is configured to include components, such as a processor and memory, configured to perform image processing operations on the received imaging data to render an image of mask 106, and may also be configured to generate and provide one or more control signals to positioning hardware associated with diffractive optic 108. As will be discussed in greater detail below, computing device 112 may also receive imaging data and perform image processing operations for an image having an amount of linear dispersion that is used to measure a resolution of the monochromator. Accordingly, computing device 112 may be configured to render such an image, and may also be configured to generate one or more resolution metrics configured to represent a spectral resolution of the monochromator, as will be discussed in greater detail below.

In various embodiments, the resolution metrics may be determined by an application executed by one or more processors of computing device 112 that is configured to determine a spectral resolution of light source 102 based on features of the image received at imaging devices 110. More specifically, each individual wavelength of light generated by light source 102 create a copy of the pattern on mask 106, where each copy for each wavelength has an amount of displacement generated based on diffractive properties, such as the additional spatial frequency carrier, of diffractive optic 108. The more wavelengths that are present in the output of light source 102, the more shift copies will be included in the image, and the more elongated the image will become. Computing device 112 may be configured to measure this amount of elongation via image processing software, and determine a range of wavelengths present, and thus determine the spectral resolution of the output of light source 102. Accordingly, an application executed by one or more processors of computing device 112 may be configured to determine an magnitude of blur present in the image in the designated direction of linear dispersion, and based on known dispersion parameters of diffractive optic 108, may determine a spectral content of the light used to generate the image, and thus determine the spectral resolution of light source 102.

FIG. 2 illustrates an example of a device for a spectrometer, configured in accordance with some embodiments. As similarly discussed above, embodiments disclosed herein generate in-situ assessments of monochromator performance to enable improved performance of monochromators. As will be discussed in greater detail below, imaging systems, such as system 200, may be configured to have multiple imaging pathways including an imaging pathway that is configured to use dispersion features of the optical output of the monochromator to generate an assessment of such monochromator performance.

In various embodiments, system 200 includes monochromator 202. As similarly discussed above, monochromator 202 is configured to generate a narrow band of wavelengths for such imaging operations. In one example, light source 102 may include a monochromator that is configured to transmit a selectable band of wavelengths of light from a wider available range of wavelengths. As shown in FIG. 2, monochromator 202 may be configured to generate an optical output comprising such a narrow band of wavelengths, and may provide the optical output to a target, such as target mask 204. The optical output may reflect off of a surface of target mask 204. In this way, monochromator 202 is configured to illuminate a surface of target mask 204 for imaging operations disclosed herein.

System 200 further includes diffractive optic 206 which is configured to implement multiple imaging modes that may implement multiple imaging operations, such as imaging and inspection of target mask 204 as well as spectral resolution measurement of monochromator 202. For example, diffractive optic 206 may be configured to include one or more zone plates configured to have diffractive features configured based on their associated imaging operations. As similarly discussed above, diffractive optic 206 may be configured to have first diffractive features used for imaging and inspection of target mask 204 in a first imaging mode. Moreover, diffractive optic 206 may be further configured to have second diffractive features used for spectral resolution measurement of monochromator 202 in a second operational mode.

In various embodiments, the first diffractive features may be included in a first zone plate, and the second diffractive features may be included in a second zone plate. Moreover, both the first zone plate and the second zone plate may be patterned on a single membrane. In this way, the first and second diffractive features may be patterned on a single diffractive optic at different physical locations of the diffractive optic. As similarly discussed above, the second diffractive features may be configured to apply an additional linear dispersion term that is used to measure the spectral resolution of monochromator 202. In various embodiments, diffractive optics may include diffractive structures that are radially symmetric thus providing dispersion that is radially symmetric. Moreover, such diffractive optics may be configured to combine the optical features of a linear grating and such a radially symmetric zone plate. In one example, a larger zone plate may be used, and an off-axis portion of the larger zone plate may be used to accommodate such additional grating features. As similarly discussed above, the additional linear dispersion term may add linear dispersion to an image generated based on a sparse array of contacts on target mask 204. Such an image may exhibit elongation along an imaging axis where such elongation is proportional to the resolution of monochromator 202.

As discussed above, a position of the diffractive optic, such as diffractive optic 206 may be changed to determine which diffractive pattern is being used. As shown in FIG. 2, a position of diffractive optic 206 may be changed along an axis of motion shown by the arrow, to shift the position of diffractive optic 206 and select which of the first diffractive features or the second diffractive features is being exposed to the output of monochromator 202 that has reflected off of target mask 204. As similarly discussed above, the position of diffractive optic 206 may be changed via manual actuation, or via electromechanical actuation controlled via a received control signal from a computing device or computing system. Moreover, such position may be changed when system 200 changes between the first and second operational modes. As shown in FIG. 2, the second diffractive features may generate the second optical output along second optical path 210 at an angular offset from first optical path 208. Accordingly, optical properties of the first diffractive features and the second diffractive features determine the angle and position at which the first optical output and the second optical output are provided while a position of monochromator 202 and a received reflected optical input from target mask 204 remains relatively constant.

More specifically, when in a first position, first diffractive features of diffractive optic 206 may generate a first optical output provided along first optical path 208 to first imaging device 212. Accordingly, a first zone plate implemented on diffractive optic 206 may use such first diffractive features to generate an image captured by first imaging device 212. As discussed above, such an image may be used for inspection and evaluation of target mask 204 during an EUV lithography process when system 200 is in a first operational mode. Moreover, when in a second position, second diffractive features of diffractive optic 206 may generate a second optical output provided along second optical path 210 to second imaging device 214. Accordingly, a second zone plate implemented on diffractive optic 206 may use such second diffractive features to generate an image captured by second imaging device 214. As discussed above, such an image may be used for performance measurement and adjustment of monochromator 202 during a maintenance or diagnostic process when system 200 is in a second operational mode.

As similarly discussed above, first imaging device 212 and second imaging device 214 may have imaging sensors such as CCD or CMOS sensors. It will be appreciated that multiple sensors may be implemented in a single imaging device, or a single imaging sensor and imaging device may be moved from a first position to a second position corresponding to appropriate imaging positions during a first operational mode and a second operational mode. Accordingly, while FIG. 2 illustrates first imaging device 212 and second imaging device 214, it will be appreciated that a single imaging device and/or a single imaging sensor may also be used.

FIG. 3 illustrates an example of a mask pattern, configured in accordance with some embodiments. As similarly discussed above, a mask may be applied to a target that will undergo lithography operations, and such a mask may be disposed as a pattern that is applied to the target via lithography operations, such as etching. Image 300 of FIG. 3 illustrates an example of such a pattern that includes first pattern portion 302, second pattern portion 304, third pattern portion 306, and fourth pattern portion 308 where such pattern portions represent portions of the pattern of the mask disposed on the target. It will be appreciated that the pattern represented in FIG. 3 is an example of a pattern provided for illustrative purposes, and any suitable pattern may be used.

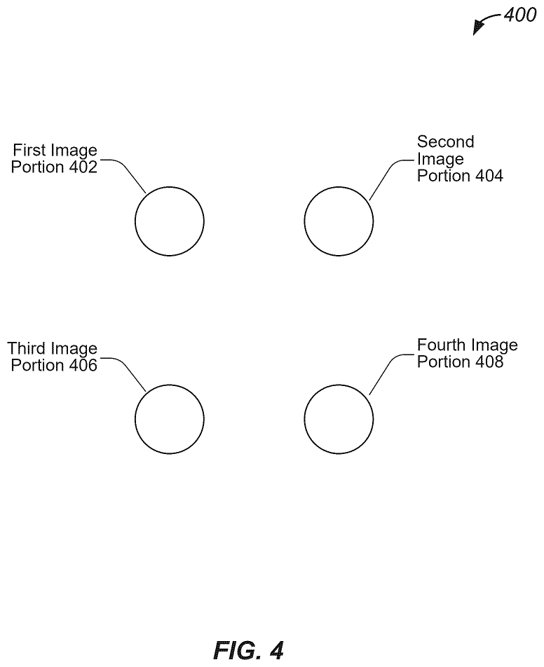

FIG. 4 illustrates an example of a diffractive optic image, configured in accordance with some embodiments. As similarly discussed above, a diffractive optic may include a zone plate having diffractive features configured to generate an optical pattern based on light received from a light source. For example, light generated by a monochromator may be provided to a target, such as a mask undergoing lithography operations, and reflected light may be received at the zone plate of the diffractive optic.

As shown in image 400 of FIG. 4, the optical pattern may include multiple different portions determined based on imaging properties of the zone plate as well as the mask pattern being imaged. In one example, the zone plate generates first image portion 402, second image portion 404, third image portion 406, and fourth image portion 408 that correspond to the pattern portions of the mask discussed above with reference to FIG. 3. In various embodiments, the image portions maybe larger than their corresponding pattern portions, as may be determined based on an amount of magnification provided by the zone plate.

In various embodiments, image 400 illustrates an optical pattern generated by a first zone plate that may be used in a first operational mode. More specifically, image 400 may represent an image generated by a diffractive optic when operating in a first operational mode used for inspection and assessment of the mask pattern. Accordingly, image 400 may be provided to a first imaging device and/or first imaging sensor along a first optical pathway for such imaging operations of the mask pattern.

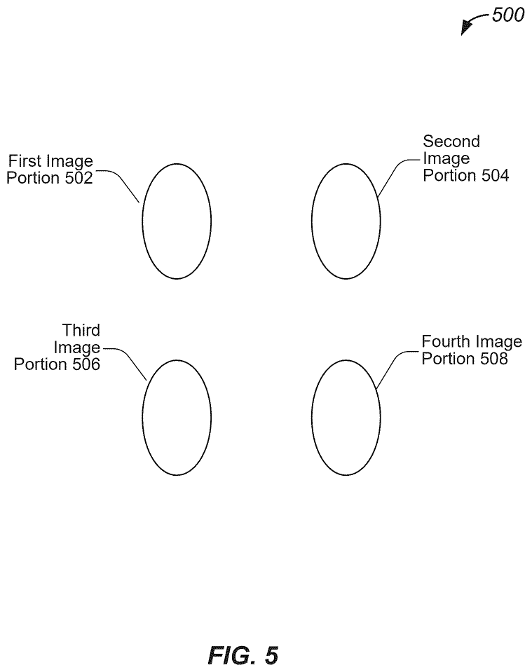

FIG. 5 illustrates another example of a diffractive optic image, configured in accordance with some embodiments. As similarly discussed above, a diffractive optic may include a zone plate having diffractive features configured to generate an optical pattern based on light received from a light source, such as light reflected off of a target mask illuminated by a monochromator.

As shown in image 500 of FIG. 5, the optical pattern may include multiple different portions determined based on interference properties of the zone plate as well as the mask pattern being imaged. In one example, the zone plate generates first image portion 502, second image portion 505, third image portion 506, and fourth image portion 508 that correspond to the pattern portions of the mask discussed above with reference to FIG. 3. In various embodiments, the image portions maybe larger than their corresponding pattern portions, as may be determined based on an amount of magnification provided by the zone plate.

In various embodiments, image 500 illustrates an optical pattern generated by a second zone plate that may be used in a second operational mode. More specifically, image 500 may represent an image generated by a diffractive optic when operating in a second operational mode used for performance assessment of the monochromator. Accordingly, image 500 may be provided to a second imaging device and/or second imaging sensor along a second optical pathway for such imaging operations of the mask pattern.

As also shown in FIG. 5, the image portions are elongated along a vertical axis of image 500 and present as elongated ovals, and not as substantially circular. In various embodiments, the amount of elongation of the image portions is proportional to the spectral resolution of the monochromator. As discussed above, the amount of elongation is a result of the linear dispersion provided by, for example, a configuration of a zone plate.

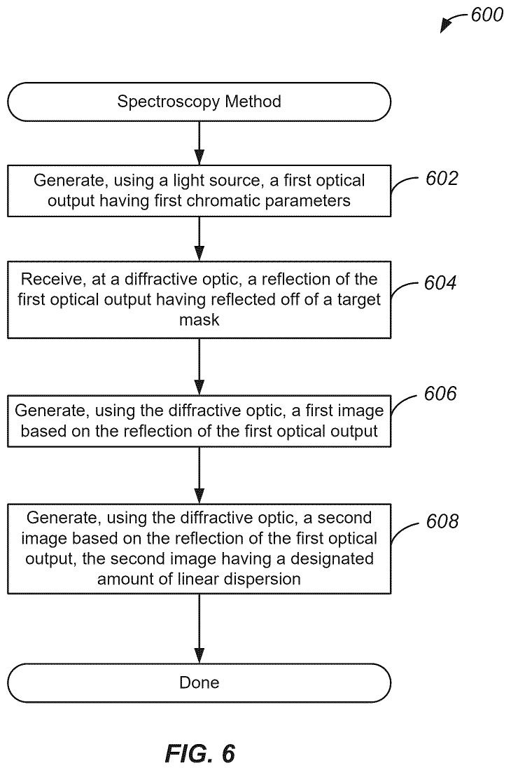

FIG. 6 illustrates an example of a method for spectrometry, performed in accordance with some embodiments. As similarly discussed above, embodiments disclosed herein generate in-situ assessments of light source performance to enable improved performance of such light sources. As will be discussed in greater detail below, a method, such as method 600, may be performed to use multiple imaging pathways including an imaging pathway used for spectrometry of a light source. As will be discussed in greater detail below, dispersion features of the optical output of the light source may be used to generate an assessment of light source performance.

Method 600 may perform operation 602 during which a first optical output may be generated using a light source. In various embodiments, the first optical output may have first chromatic parameters. As similarly discussed above, the light source may be an intrinsically narrow-band light source, or may be a light source rendered more narrow band through the use of a secondary component such as a monochromator, and the first chromatic parameters may represent wavelengths of light emitted by the light source and included in the first optical output.

Method 600 may perform operation 604 during which the first optical output may be received at a diffractive optic. As similarly discussed above, the first optical output may be received after having reflected off of a target mask. Accordingly, the light source may illuminate the target mask, and the reflection including an image of the target mask may be received at the diffractive optic.

Method 600 may perform operation 606 during which a first image may be generated, using the diffractive optic, based on the reflection of the first optical output. As similarly discussed above, the diffractive optic may be in a first position associated with a first operational mode used for microscopy operations that may include imaging and inspection of the target mask. Accordingly, the optical output of the diffractive optic may be provided to an imaging device to render the first image of the target mask for such microscopy operations.

Method 600 may perform operation 608 during which a second image may be generated, using the diffractive optic, based on the reflection of the first optical output. As similarly discussed above, the diffractive optic may be in a second position associated with a second operational mode used for spectrometry operations used to assess a performance of the light source. Accordingly, the optical output of the diffractive optic may be provided to the imaging device to render a second image of the target mask for such spectrometry operations. As discussed above, the second image has a designated amount of linear dispersion that is proportional to a spectral resolution of the light source.

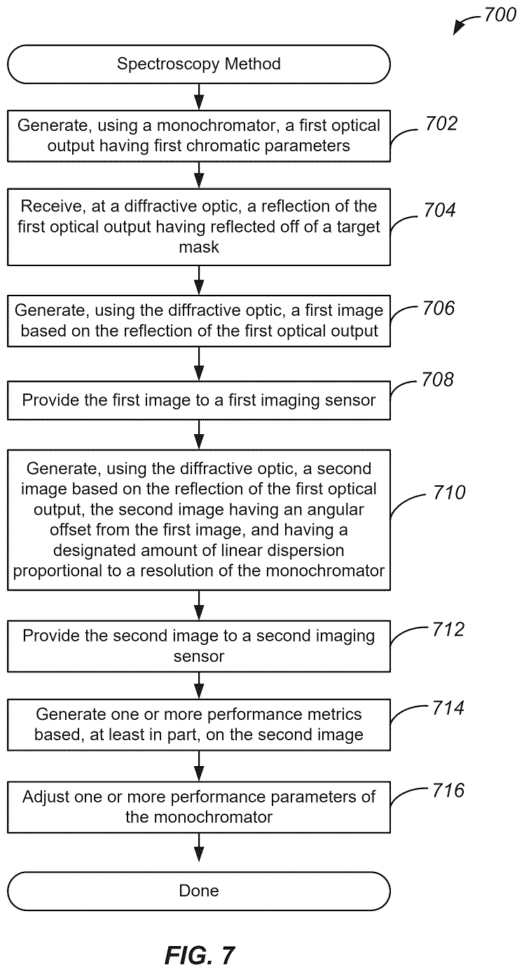

FIG. 7 illustrates another example of a method for spectrometry, performed in accordance with some embodiments. As similarly discussed above, embodiments disclosed herein generate in-situ assessments of monochromator performance to enable improved performance of such monochromators. As will be discussed in greater detail below, a method, such as method 700, may be performed to use multiple imaging pathways including an imaging pathway used for spectrometry of a monochromator. As will be discussed in greater detail below, dispersion features of the optical output of the monochromator may be used to generate an assessment of monochromator performance.

Method 700 may perform operation 702 during which a first optical output having first chromatic parameters may be generated. In various embodiments, the first optical output may be generated using a monochromator. As similarly discussed above, the monochromator may be used to generate a narrow band optical output, and the first chromatic parameters may represent wavelengths of light emitted by the monochromator and included in the first optical output used for microscopy operations.

Method 700 may perform operation 704 during which a reflection of the first optical output may be received after having reflected off of a target mask. The reflection may be received at a diffractive optic after having reflected off of the target mask. Accordingly, the monochromator may generate the first optical output that is used to illuminate the target mask, and a reflection including an image of the target mask may be received at the diffractive optic.

Method 700 may perform operation 706 during which a first image may be generated based on the reflection of the first optical output. As similarly discussed above, the first image may be generated using the diffractive optic. More specifically, the diffractive optic may be configured to have various diffractive features. For example, the diffractive optic may be configured to have multiple optical gratings implemented as different zone plates that are patterned on a single optical membrane. In some embodiments, the first image may be generated using a first zone plate included in the diffractive optic when the diffractive optic is in a first position and is positioned such that it is exposed to and receives the reflection of the first optical output. For example, the first zone plate may be positioned in a pathway of the reflection of the first optical output, as may be determined based on an incidence angle of the first optical output relative to the target mask. It will be appreciated that such angles and positions may have been determined by an entity, such as a manufacturer, during a design process.

Method 700 may perform operation 708 during which the first image may be provided to a first imaging sensor. Accordingly, an optical output of the first zone plate may be provided to a first imaging sensor and may be rendered as a digital image by the imaging sensor and an associated computing device. As similarly discussed above at least with reference to FIG. 4, the first image may include a representation of the target mask that may be used for lithography and microscopy operations, such as inspection and assessment of features, such as uniformity, of the target mask as may be performed in the first operational mode.

Method 700 may perform operation 710 during which a second image may be generated based on the reflection of the first optical output. In various embodiments, the second image may be generated using the diffractive optic. More specifically, the diffractive optic may be configured to include additional diffractive features. For example, the diffractive optic may be configured to include a second zone plate. In some embodiments, the second zone plate may be implemented on a same optical membrane as the first zone plate. Accordingly, the second image may be generated using the second zone plate included in the diffractive optic when the diffractive optic is in a second position and is positioned such that it is exposed to and receives the reflection of the first optical output from the target mask. For example, the second zone plate may be positioned in a pathway of the reflection of the first optical output, as may be determined based on an incidence angle of the first optical output relative to the target mask. Moreover, the second image may have a designated amount of linear dispersion proportional to a resolution of the monochromator, and such a linear dispersion may be generated based on diffractive features of the second zone plate.

As discussed above, a position of the diffractive optic may be changed from the first position to the second position to change which zone plate is within the pathway of the reflection of the target mask and is exposed to the reflection of the first optical output. Accordingly, in some embodiments, between operation 708 and operation 710, or as part of operation 710, a position of the diffractive optic may be changed from the first position to the second position.

Method 700 may perform operation 712 during which the second image may be provided to a second imaging device. Accordingly, an optical output of the second zone plate may be provided to a second imaging sensor and may be rendered as a digital image by the second imaging sensor and an associated computing device. In various embodiments, the second image may be provided along an optical path that has an angular offset from an optical path of the first image, as similarly discussed above with reference to FIG. 2A, thus enabling the use of two different imaging sensors corresponding to the two different operational modes.

It will be appreciated that while embodiments disclosed herein describe the use of two imaging sensors, a single imaging sensor may be used, and a position of the imaging sensor may be toggled between positions corresponding to their respective operational modes. More specifically, the first imaging sensor and the second imaging sensor may be the same imaging sensor that is coupled to a positioning device or system, such as an electromechanical rail system discussed above. The imaging sensor may be positioned at a first imaging position in a first operational mode, and may be positioned at a second imaging position in a second operational mode where such imaging positions are determined based on optical paths of the first and second images. In some embodiments, a single imaging sensor may be used that is configured to be large enough to capture both imaging positions. In this example, a single imaging sensor may be used and may remain stationary while the zone plate is moved.

Method 700 may perform operation 714 during which one or more monochromator performance metrics may be generated based on the second image. As similarly discussed above at least with reference to FIG. 5, the second image may include a representation of the target mask that may be used for spectrometry operations, such as performance assessment of the monochromator as may be performed in the second operational mode. The second image may be elongated along an imaging axis in accordance with the linear dispersion provided by the second zone plate along with the spectral characteristics of the light leaving the monochromator. In various embodiments, the linear dispersion present in the second image may be used by, for example, a computing device that receives the second image to generate a performance metric for the monochromator based on an observed amount of blur in the image. As discussed above, the performance metric may represent a spectral resolution of the monochromator.

Method 700 may perform operation 716 during which one or more performance parameters of the monochromator may be adjusted. Accordingly, the performance metrics generated during operation 714 may be used to identify one or more changes to operational parameters of the monochromator. In one example, the resolution of the monochromator may be adjusted by controlling the longitudinal position of entrance and/or exit slits of the monochromator. It will be appreciated that techniques for control of the performance of the monochromator will be determined based on a configuration and type of the monochromator. Accordingly, such changes to operational parameters may be any suitable calibration operation as may be determined based on the manufacture and configuration of the monochromator itself.

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

What is claimed is:

1. A system comprising:
a light source configured to generate a first optical output;
a diffractive optic configured to receive at least a portion of the first optical output from the light source, the diffractive optic being configured to generate a first image when in a first position, and further configured to generate a second image when in a second position, the second image having a designated amount of linear dispersion;
an imaging device configured to receive at least the second image; and
a computing device comprising one or more processors configured to generate one or more performance metrics for the light source based, at least in part, on the second image.

2. The system of claim 1, wherein the light source comprises a monochromator, and wherein the first optical output is used to illuminate a target mask associated with lithography operations.

3. The system of claim 1, wherein the diffractive optic comprises:
a first zone plate configured to generate the first image; and
a second zone plate configured to generate the second image.

4. The system of claim 3, wherein the diffractive optic is configured to toggle between a first position and a second position, the first position exposing the first zone plate to the at least a portion of the first optical output, and the second position exposing the second zone plate to the at least a portion of the first optical output.

5. The system of claim 3, wherein the first zone plate and the second zone plate are implemented on a same optical membrane.

6. The system of claim 3, wherein the linear dispersion is generated based, at least in part, on diffractive features of the second zone plate.

7. The system of claim 1, wherein the one or more performance metrics are generated based, at least in part, on a magnitude of the linear dispersion included in the second image.

8. The system of claim 1, wherein the computing device is further configured to adjust one or more operational parameters of the light source based on the one or more performance metrics.

9. The system of claim 8, wherein the adjusting comprises:
adjusting a bandwidth setting of the light source.

10. A device comprising:
a diffractive optic configured to receive at least a portion of a first optical output from a light source, the diffractive optic being configured to generate a first image when in a first position, and further configured to generate a second image when in a second position, the second image having a designated amount of linear dispersion;
one or more imaging sensors configured to receive at least the second image; and
one or more processors configured to generate one or more performance metrics for the light source based, at least in part, on the second image.

11. The device of claim 10, wherein the light source comprises a monochromator, and wherein the first optical output is used to illuminate a target mask associated with lithography operations.

12. The device of claim 10, wherein the diffractive optic comprises:
a first zone plate configured to generate the first image; and
a second zone plate configured to generate the second image.

13. The device of claim 12, wherein the diffractive optic is configured to toggle between a first position and a second position, the first position exposing the first zone plate to the at least a portion of the first optical output, and the second position exposing the second zone plate to the at least a portion of the first optical output.

14. The device of claim 12, wherein the first zone plate and the second zone plate are implemented on a same optical membrane, and wherein the linear dispersion is generated based, at least in part, on diffractive features of the second zone plate.

15. The device of claim 10, wherein the one or more performance metrics are generated based, at least in part, on a magnitude of the linear dispersion included in the second image, and wherein the one or more processors are further configured to adjust one or more operational parameters of the light source based on the one or more performance metrics.

16. A method comprising:
receiving at least a portion of a first optical output from a light source;
selecting a position of a diffractive optic, the diffractive optic being toggleable between a first position used to generate a first image and a second position used to generate a second image;
generating, using the diffractive optic, a second image when in a second position, the second image having a designated amount of linear dispersion determined based, at least in part, on diffractive features of the diffractive optic;
receiving the second image at an imaging device; and
generating, using one or more processors, one or more performance metrics for the light source based, at least in part, on the second image.

17. The method of claim 16, wherein the light source comprises a monochromator, and wherein the first optical output is used to illuminate a target mask associated with lithography operations.

18. The method of claim 16, wherein the diffractive optic comprises a first zone plate and a second zone platen, and wherein the method further comprises:
generating, using the second zone plate, the second image.

19. The method of claim 18, wherein the first zone plate and the second zone plate are implemented on a same optical membrane, and wherein the linear dispersion is generated based, at least in part, on diffractive features of the second zone plate.

20. The method of claim 16, wherein the one or more performance metrics are generated based, at least in part, on a magnitude of the linear dispersion included in the second image, and wherein the method further comprises:
adjusting one or more operational parameters of the light source based on the one or more performance metrics.
